(19) United States
(12) Patent Application Publication
(10) Pub. No.: US 2009/0169868 A1
(43) Pub. Date: Jul. 2, 2009

(54) Methods and apparatus for transferring a material onto a substrate using a resonant infrared pulsed laser

(75) Inventors: Richard F. Haglund, JR., Brentwood, TN (US); Nicole L. Dygert, Nashville, TN (US); Kenneth E. Schriver, Nashville, TN (US)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Vanderbilt University, Nashville, TN (US)

(21) Appl. No.: 11/337,301

(22) Filed: Jan. 23, 2006

Related U.S. Application Data
(63) Continuation-in-part of application No. 10/059,978, filed on Jan. 29, 2002, now Pat. No. 6,998,156.
(60) Provisional application No. 60/714,819, filed on Sep. 7, 2005.

(51) Int. Cl. B32B 5/16; B05D 3/00; B05D 3/06; C23C 16/56; B32B 27/00

(52) U.S. Cl. 428/327; 427/532; 427/555; 118/723 R; 428/473.5; 428/523; 428/421; 428/500

(57) ABSTRACT

A method for transferring a material onto a substrate. In one embodiment, the method includes the steps of directing a coherent light of a wavelength resonant with a vibrational mode of the material at the material to vaporize the material, depositing the vaporized material on the substrate in a form that is essentially same chemically as the material, and selectively heating the deposited material at one or more positions of the substrate to form a film thereon.

### CROSS-REFERENCE TO RELATED PATENT APPLICATION

This application is a continuation-in-part of U.S. patent application Ser. No. 10/059,978, filed Jan. 29, 2002, entitled “Deposition of Thin Films Using an Infrared Laser,” by Daniel Bubb, James Horwitz, John Callahan, Richard Haglund, Jr. and Michael Papantonakis, the disclosure of which is hereby incorporated herein by reference in its entirety. This application also claims the benefit, pursuant to 35 U.S.C. §119(e), of U.S. provisional patent application Ser. No. 60/714,819, filed Sep. 7, 2005, entitled “A Resonant Infrared Pulsed Laser System for Transferring a Material Onto a Substrate and Applications of Same,” by Richard F. Haglund, Jr., Nicole L. Dygert, and Kenneth E. Schriver, which is incorporated herein by reference in its entirety.

Some references, which may include patents, patent applications and various publications, are cited and discussed in the description of this invention. The citation and/or discussion of such references is provided merely to clarify the description of the present invention and is not an admission that any such reference is “prior art” to the invention described herein. All references cited and discussed in this specification are incorporated herein by reference in their entireties and to the same extent as if each reference was individually incorporated by reference. In terms of notation, hereinafter, “[n]” represents the nth reference cited in the reference list. For example, [3] represents the 3rd reference cited in the reference list, namely, M. R. Papantonakis, and R. F. Haglund, Jr., Picosecond pulsed laser deposition at high vibrational excitation density: the case of poly(tetrafluoroethylene). Applied Physics A—Materials Science & Processing, 2004, 79(7): p. 1687-1694.

### STATEMENT OF FEDERALLY-SPONSORED RESEARCH

The present invention was made with Government support awarded by the Naval Research Laboratory under Contract No. N00173-05-P-0059; the Department of Defense Medical Free-Electron Laser Program under Contract No. F49620-01-1-0429); and the National Science Foundation IGERT Program under Contract No. DGE-0333392. The United States Government may have certain rights to this invention pursuant to these grants.

### FIELD OF THE INVENTION

The present invention generally relates to pulse laser deposition, and in particular to methods and apparatus for transferring a material onto a substrate with a resonant infrared pulsed laser.

### BACKGROUND OF THE INVENTION

Infrared pulsed laser deposition (hereinafter “PLD”) was first reported in 1960's but did not emerge as a thin film coating technology at that time for number of reasons. These include the slow repetition rate of the available lasers, and the lack of commercially available high power lasers. At that time, infrared PLD used infrared laser light of 1.06 μm which was not resonant with any single photon absorption band of the material being deposited. Although PLD developed through the years it was not until late 1980's that ultraviolet PLD became popular with the discovery of complex superconducting ceramics and the commercial availability of high energy, high repetition rate lasers. Ultraviolet PLD is now a common laboratory technique used for the production of a broad range of thin film materials.

Ultraviolet PLD has been an extremely successful technique for the deposition of thin films of a large variety of complex, multi-component inorganic materials. Ultraviolet PLD has also been applied to the growth of thin polymeric and organic films, with varying degrees of success. It has been shown that polymethyl methacrylate, polytetrafluoroethylene and polyalphamethyl styrene undergo rapid depolymerization during ultraviolet laser ablation, with the monomer of each strongly present in the ablation plume. The photochemical modification occurs because the energy of the ultraviolet laser causes the irradiated material to be electronically excited. The geometry of the excited electronic state can be very different from the ground electronic state. Relaxation of the excited state can be to either the ground state of the starting material, or the ground state of a geometrically different material. Deposited films are therefore photochemically modified from the starting material, showing a dramatic reduction in the number average molecular weight. For these polymers, depositing the film at an elevated substrate temperature can increase the molecular weight distribution of the deposited thin film material. On arrival, monomeric material repolymerizes on the heated substrate surface, with degree of repolymerization being determined by the thermal activity of the surface. Therefore, even in some of the most successful cases of ultraviolet PLD, the intense interaction between the target material and laser leads to chemical modification of the polymer.

An alternative approach to PLD of polymeric materials with ultraviolet lasers is matrix-assisted pulsed laser evaporation (hereinafter “MAPLE”), disclosed in U.S. Pat. No. 6,025,036 and others, where roughly 0.1-1% of a polymer material to be deposited is dissolved in an appropriate solvent and frozen to form an ablation target. The ultraviolet laser light interacts mostly with the solvent and the guest material is evaporated much more gently than in conventional PLD. While this technique can produce smooth and uniform polymer films, it requires that the polymer of interest be soluble in a non-interacting solvent. Finding a suitable solvent system that is also non-photochemically active is a significant challenge and limits the usefulness of the technique. There are examples where electronic excitation of the solvent/polymer system has been observed to produce undesirable photochemical modification of the polymer, such as reduction in the average weight average molecular weight. An additional disadvantage of the matrix-assisted pulsed laser evaporation is that the deposition rate is about an order of magnitude lower than conventional PLD, which can render matrix-assisted pulsed laser evaporation ineffective for applications that require thick, i.e., greater than about 1 μm, coatings.

The ability to deposit polymeric materials in the form of a thin film is important for a wide range of uses including electronics, chemical sensors, photonics, analytical chemistry and biological sciences and technologies. An important biomedical application of polymer thin films is for biocompatible polymer thin films on drug particles. The coating serves to both delay and regulate the release of the drug in the body. Two techniques that have been demonstrated in the coating of drug particles include wet chemical technique and a vapor deposition technique. In the wet chemical technique, the coated particle can be more than 50% coating on weight bases. A coating that minimizes the coating to drug weight ratio is desired for obvious reasons. It is also important to control the thickness of the deposited film since control of the dissolution rate governs the rate of drug delivery. While UVPLD has been used to deposit much thinner (on the order of a few hundred angstroms) coatings on drug particles, the deposition process introduces significant and undesirable chemical modification in the coating material as a consequence of the ultraviolet excitation.

Polyimides are unique polymeric materials characterized by high mechanical strength, good dielectric properties, and outstanding oxidative and thermal stability. They are a promising candidate for integration into mesoscale devices, including micro-electro-mechanical systems (hereinafter “MEMS”), however, bottom-up manipulation of these and other thermoset polymers is difficult on length scales below a few microns. Laser processing of polyimides has been largely limited to ablation.

Therefore, a heretofore unaddressed need still exists in the art to address the aforementioned deficiencies and inadequacies.

### SUMMARY OF THE INVENTION

The present invention, in one aspect, relates to a method for transferring a material onto a substrate. In one embodiment, the method includes the steps of directing a coherent light of a wavelength resonant with a vibrational mode of the material at the material to vaporize the material, depositing the vaporized material on the substrate in a form that is essentially same chemically as the material, and selectively heating the deposited material at one or more positions of the substrate to form a film thereon. The thickness of the film is in a range of a single molecular size to microns, preferably, in a range of about 10 angstroms to 1 μm. The selectively heating step may include the step of heating the deposited material according to a predetermined pattern. In one embodiment, the selectively heating step is performed through a laser light absorption. In another embodiment, the selectively heating step is performed resistively and electrically.

The material comprises one of organic, inorganic, biological materials and mixtures thereof. In one embodiment, the material includes a polymeric material. The polymeric material includes a thermosetting polymer, a thermoplastic polymer, or a polymer precursor solution. In one embodiment, the thermosetting polymer has polyimide (hereinafter “PI”). The thermoplastic polymer has polyethylene glycol (hereinafter “PEG”), polystyrene, polytetrafluoroethylene (hereinafter “PTFE”) or mixtures thereof. The polymer precursor solution includes a concentration of pyromellitic dianhydride (hereinafter “PMDA”) and 4,4′ oxidianiline (hereinafter “ODA”) dissolved in N-methylpyrrolidinone (hereinafter “NMP”).

The vibrational mode of the material is in a range of about 0.1 μm to 10,000/m. In one embodiment, the vibrational mode of the material is in the infrared region of about 1 μm to 15 μm, preferably at about 3.45 μm.

In one embodiment, the coherent light comprises pulses of infrared laser with a fluency in a range of about 0.1 to 10 J/cm², where the pulses of infrared laser have a pulse duration in a range of about 100 fs to 5 ps and a pulse repetition frequency in a range of about 1 MHz to 3 GHz. In one embodiment, the pulses of infrared laser are delivered in the form of a pulse train in a burst of a micropulse mode lasting microseconds to milliseconds. In another embodiment, the pulses of infrared laser are delivered in the form of a pulse train on a continuous basis. Alternatively, the coherent light comprises an infrared laser of a continuous wave mode. The resonant wavelength of the coherent light is determinable from an absorption spectrum of the material.

In another aspect, the present invention relates to a film made according to the method as disclosed above.

In yet another aspect, the present invention relates to a method for transferring a material onto a substrate, where the substrate is formed such that the material is unable to wet it. In one embodiment, the method has the steps of directing a coherent light of a wavelength resonant with a vibrational mode of the material at the material to vaporize the material, depositing the vaporized material on the substrate in a form that is essentially same chemically as the polymeric material, and heating the deposited material through the substantially entire surface of the substrate in contact with the deposited material to form a plurality of nanoscale grains of the material thereon. The material comprises one of organic, inorganic, biological materials and mixtures thereof.

In a further aspect, the present invention relates to a plurality of nanoscale grains of an organic and/or polymeric material made according to the invented method.

In yet a further aspect, the present invention relates to an apparatus for transferring a material onto a substrate. The material includes one of organic, inorganic, biological materials and mixtures thereof. In one embodiment, the material has a polymeric material. In one embodiment, the apparatus has a coherent light source of a wavelength resonant with a vibrational mode of the material, wherein the resonant wavelength is determinable from an absorption spectrum of the material. In one embodiment, the coherent light source includes an infrared laser. The infrared laser is capable of emitting pulses of coherent light with a fluency in a range of about 0.1 to 10 J/cm², where the pulses of coherent light have a pulse duration in a range of about 100 fs to 5 ps at a pulse repetition frequency in a range of about 1 MHz to 3 GHz. The infrared laser in one embodiment is configured such that the pulses of coherent light are delivered in the form of a pulse train in a burst of a micropulse mode lasting microseconds to milliseconds. In another embodiment, the infrared laser in one embodiment is configured such that the pulses of coherent light are delivered in the form of a pulse train on a continuous basis. In one embodiment, the infrared laser is capable of emitting coherent light of a continuous wave mode. The infrared laser includes a free electron laser (hereinafter “FEL”), a CO₂ laser, an OPO laser, a N₂ laser, or an Er:YAG laser.

Furthermore, the apparatus includes means for directing the coherent light at the polymeric material to vaporize the material, means for depositing the vaporized material on the substrate in a form that is essentially same chemically as the material, and means for selectively heating the deposited material on the substrate.

In one embodiment, the selectively heating means comprises a laser capable of delivering a radiation according to a predetermined pattern. In another embodiment, the selectively heating means comprises one or more electrical resistors, where the one or more electrical resistors are adapted for heating the deposited material according to a predetermined pattern. In yet another embodiment, the selectively heating means is capable of heating the deposited material at one or more positions of the substrate to form a film thereon. Alternatively, if the substrate is formed such that the material is unable to wet it, the selectively heating means is capable of heating the deposited material through the substantially entire surface of the substrate in contact with the deposited material to form a plurality of nanoscale grains of the material thereon. In one embodiment, the selectively heating means is capable of heating the substrate upon which the material is deposited.

In one aspect, the present invention relates to a method for transferring a starting material onto a substrate. In one embodiment, the method comprises the steps of vaporizing a starting material, depositing the vaporized material on the substrate, and curing the deposited material on the substrate by cross linking to turn it into a material that is different from the starting material on the substrate.

In one embodiment, the vaporizing steps is performed with coherent light of an infrared wavelength resonant with a vibrational mode of the starting material, wherein the resonant wavelength is determinable from an infrared absorption spectrum of the starting material. The curing step may comprise the step of selectively heating the deposited material at one or more positions of the substrate. In one embodiment, the curing step is performed through a laser light absorption. In another embodiment, the curing step is performed resistively and electrically.

The starting material comprises a precursor solution. In one embodiment, the precursor solution comprises a polyamic acid precursor, and the material comprises polyimide. In another embodiment, the precursor solution comprises a resonant absorbing material characterized in that an ablation process is substantially slow and low-temperature, wherein the resonant absorbing material comprises a solvent N-methyl pyrrolidinone (NMP). Alternatively, the precursor solution comprises a concentration of pyromellitic dianhydride (PMDA) and 4,4′ oxidianiline (ODA) dissolved in N-methyl pyrrolidinone (NMP).

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

FIG. 1 shows schematically an apparatus according to one embodiment of the present invention.

FIG. 2 shows schematically a FEL pulse structure that is used to practice the present invention.

FIG. 3 shows images of the plume of a poly(amic)acid (PPA) solution excited by a N₂ laser according to one embodiment of the present invention: (a)-(c) different laser fluences.

FIG. 4 shows images of the plume of a target material excited by a N₂ laser with varied time delays and a fixed fluence according to one embodiment of the present invention: (a)-(e) a neat solvent of N-methylpyrrolidinone (NMP), and (f)-(j) a poly(amic)acid (PPA) solution.

FIG. 5 shows images of a resonant infrared pulse laser deposition (RIR-PLD) of polyimide (PI) excited by a laser at a wavelength of 3.45 μm according to one embodiment of the present invention: (a) in air, (b) and (c) in vacuum.

FIG. 6 shows images of ablation of polymeric films by a laser of a wavelength of 5.9 μm according to one embodiment of the present invention: (a) a PI film, and (b) a PPA film.

FIG. 7 shows schematically mechanisms of transferring polytetrafluoroethylene (PTFE) onto a substrate: (a) by a plasma-enhanced chemical vapor deposition (PECVD/CVD) method, (b) by a conventional PLD method, and (c) by a RIR-PLD method according to one embodiment of the present invention.

FIG. 8 shows images of (a) a substrate of an uncoated Ni mesh and (b) a coated PTEE film with a thickness of 200 nm onto the substrate according to one embodiment of the present invention.

FIG. 9 shows graphs of (a) a deposition rate and (b) transmission of a RIR-PLD of PTFE according to one embodiment of the present invention.

FIG. 10 is a graph of thin film absorption spectra for a target polyethylene glycol (PEG) transferred onto a substrate by means of a RIR-PLD according to one embodiment of the present invention.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like parts throughout the views. As used in the description herein and throughout the claims that follow, the meaning of “a,” “an,” and “the” includes plural reference unless the context clearly dictates otherwise. Also, as used in the description herein and throughout the claims that follow, the meaning of “in” includes “in” and “on” unless the context clearly dictates otherwise.

The description will be made as to the embodiments of the present invention in conjunction with the accompanying drawings 1-10. In accordance with the purposes of this invention, as embodied and broadly described herein, this invention, in one aspect, relates to a method for transferring a starting target material from its starting condition in a solid form, through a vapor state, and depositing the material in a solid state on a substrate which is, preferably, essentially the same as the starting material, i.e., a method for coating surfaces with a layer of a material which has been transported to the vapor phase using resonant vibrational mode PLD.

In one embodiment, the method comprises the step of directing a coherent light at a starting target material to vaporize the target material, where the coherent light has a wavelength that is resonant with a vibrational mode of the target material. In one embodiment, the resonant wavelength of the coherent light is determinable from an absorption spectrum of the target material. The method further comprises the steps of depositing the vaporized material on the substrate in a form that is essentially same chemically as the material, and selectively heating the deposited material at one or more positions of the substrate to form a film thereon. In a preferred embodiment, this deposited solid thin film has substantially the same chemical composition and structure as the target material.

This technique can be used for a wide range of materials including polymeric thin film materials for application ranging from electronics to biological sciences. The technique is general and can be extended to all organic, organometallic, inorganic, and biological materials or combinations of materials, particularly in the form of thin films, and to any material which can be transferred to a substrate by vaporizing the target material by resonantly exciting a vibrational mode in the material whereby a vapor plume is formed which is deposited typically in the form of a solid thin film on a substrate. For example, the target material can be a polymeric material including a thermosetting polymer such as polyimide, or a thermosetting polymer such as PEG, polystyrene, PTFE. The target material can also be a polymer precursor solution comprising a concentration of PMDA and ODA dissolved in NMP.

Preferably, the current invention is employed for a material having vibrational modes in a range of about 0.1 μm to 10,000 μm. Most organics and polymers have rich vibrational spectra in the infrared region of about 1-15 μm.

Both the excitation light and a vibrational band of the material will have finite bandwidths. A feature of this invention is the overlap between excitation light and a vibrational band. There should be sufficient overlap for the excitation light to excite a vibrational band to cause vaporization of the target material. More typically, the peak of the excitation light is at the same wavelength as the peak of a vibrational band. More preferably, the excitation light has a peak and a bandwidth that avoids, or at least mitigates, the excitation of modes that cause changes to the chemical composition or other changes of the target molecule. Resonant excitation means that a portion of the linewidth of the illuminating light source overlaps with the infrared absorption band of the target material.

In one embodiment, the output of a high power, pulsed infrared laser is tuned to be resonant with a vibrational mode in the material. Resonant excitation and evaporation of the material on a target leads to formation of a plume of the target material and its deposition on a substrate in the form of a solid film, particularly thin film that has essentially the same chemical composition and structure as the target material.

Resonant infrared laser deposition is unique when compared to conventional PLD in that it takes advantage of the molecular structure of the material and uses mode specific heating to localize and control the deposited laser energy. The highly vibrationally excited material remains in its ground electronic state but has sufficient internal energy to overcome intermolecular binding energy of the material and be transported into the gas phase usually without significant photochemical modification, including rupture of the bonds between repeating units of a polymeric material. If a material is irradiated with higher energy lasers, such as the ultraviolet region, then the bonds between repeating units of a polymeric material, and possibly other bonds in the material, can rupture or react and lead to modification of the material. The mode specific heating of the resonant excitation allows deposition of a wide variety of photochemically and thermally unstable or labile materials in thin film form.

The non-electronic, resonant infrared laser deposition is characterized by the selection of a band in the infrared absorption spectrum of the coating material, particularly polymeric coating material. The operational region in the absorption spectrum corresponds to molecular vibrational states in the approximate region of 100-5000 cm⁻¹, particularly the infrared region of 1-15 μm, and especially 2-10 μm. Transfer of sufficient energy to a coating target material is made to cause desorption of the target material and deposition thereof from a vapor state onto a substrate without degradation. Only enough energy is transferred to the target material to keep the material in its ground electronic state and below an excited electronic excitated state. One way to determine if the appropriate vibrational energy was injected (e.g. to desorb the material so that it remains at the ground electronic state and below its excited electronic state, and thus does not undergo chemical and structural modification) is to measure the infrared absorption spectrum of the deposited material and compare this spectrum to the spectrum of the original material. If the spectra essentially match, then the material has not undergone any considerable chemical and/or structural modification. If too much energy has been injected, to where the material can be promoted to an excited electronic state then the material can be chemically and/or structurally modified to the point where it is not useful for the intended purpose. Chromatography can be used to determine appearance of photochemical modification in a material. Also, other analytical techniques, such as mass spectrum and NMR, can be used to verify the match between the target and the deposited material.

In other words, the appropriate wavelength of light, corresponding to resonant vibrational excitation, can be determined by examining the infrared absorption spectrum of the target material that is to be transferred onto a substrate in solid form via laser evaporation. The infrared spectrum has characteristic absorption bands that are used to identify the chemical structure of the material. The resonant excitation wavelength can be determined by identifying the wavelength associated with one of the absorption bands, and then using a light source, such as a tunable laser in the infrared region or a fixed frequency laser that is resonant with the vibrational absorption band, to deliver the resonant energy to the target material, as by shining the light onto the material. Light of more than one resonant wavelength can be used. Deposition rates of a material vary depending on what resonant wavelength is used and the desired deposition rate can be measured and selected experimentally.

After depositing the plume of the vaporized material on the substrate, a thin film is formed by subsequently curing. In one embodiment, a thin precursor film is selectively irradiated by a laser in such a way that the cured material appears only where the laser light causes the precursor to exceed the curing temperature threshold. Alternatively, the substrate can be selectively (either resistively/electrically or by laser light absorption), leading to topically selected growth of the polymer film. In another embodiment, if the substrate is formed such that the polymer cannot wet it, a plurality of nanoscale grains of the polymer is generated by heating the entire surface of the substrate. Additionally, the deposited material on the substrate may selectively be heated according to a predetermined pattern.

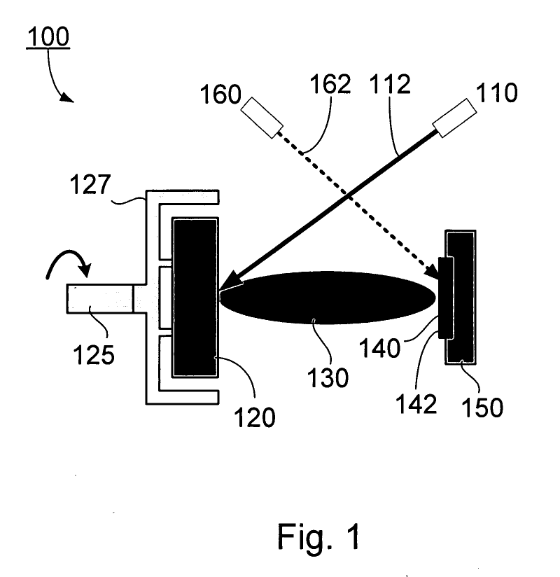

The thickness of the film formed on a substrate from a target material by means of a laser tuned to the desired wavelength, can be controlled down to molecular level. Preferably, the thickness of the film ranges from about 10 angstroms to 1 μm. This can be done in conjunction with an apparatus of the present invention shown in FIG. 1 by counting the laser pulses. Since every time the laser is fired at the target material, the same amount of vapor is produced and the same amount of the material is deposited on the substrate from the vapor, a certain number of laser pulses will give a predetermined thickness of deposited material on the substrate. For instance, by firing the FEL laser 100 times (100 macropulses) of light at 3.4 μm at a target material polyethylene glycol of 1450 average molecular weight, a desired thickness of the material can deposited on a substrate maintained at room temperature.

Referring now to FIG. 1, an apparatus 100 for transferring a material onto a substrate according to one embodiment of the present invention is shown. The apparatus 100 has a first laser source 110 with a wavelength resonant with a vibrational mode at a target material 120 to vaporize the target material 120 into a laser plume 130, where the resonant wavelength is determinable from an absorption spectrum of the target material 120. The target material 120 is placed in a rotatable platform 125 that is associated with a target carrousel 127. The substrate 140 is positioned on a heatable sample stage 150 and has a surface 142 facing opposite to the target material 120 such that the laser plume 130 of the vaporized target material is capable of reaching the surface 142 of the substrate 140 and being deposited thereon. Once the target material 120 is deposited on the surface 142 of the substrate 140 by means of the laser plume 130, it can be thermally cured to form a film or a collection of grains of the target material 120. Curing can be done by the first laser source 110, in which case the relative position and orientation of the sample stage 150 is adjustable so that the laser light 112 from the first laser source 110 is reachable to the target material 120 deposited on the substrate 140. Curing can also be done by an optional, second laser source 160, in which case the second laser source 160 is positioned such that the laser light 162 from the second laser source 160 is reachable to the target material 120 deposited on the substrate 140 Each of the first laser source 110 and second laser source 160 can be mounted to a movable stage so that each can move in at least one trajectory in relation to the surface 142 of the substrate 140 and selectively heat the target material 120 deposited on the substrate 140 at one or more positions, which results a film in a pattern and/or with selected growth. Curing can also be done by other means such as electrical current heating, in which case one or more electrical resistors are associated with the stage for heating the deposited material. The stage itself can be conductive to function as an electrical heater. The one or more resistors can be placed according to a predetermined pattern to selectively heat the target material deposited on the substrate.

The substrate 140 can be of any solid material that can be vaporized by resonant infrared excitation, including organic, especially polymeric materials, inorganic materials, and biological materials. The substrates 140 can be any material that will accept the vapor as a deposited coating and can include planar or non-planar surfaces as well as particles.

The apparatus shown in FIG. 1 can be used to coat substrate surfaces with a thin layer of a polymeric material, or any other material that can be vaporized by application of infrared energy to the target material. The apparatus can operate either in vacuum or in air. The product is a coated substrate wherein the coating is a thin film adhering to the substrate and being essentially the same as the original target material without having undergone any essential chemical and/or structural modification.

In one embodiment, the first laser source includes a tunable infrared laser that is capable of emitting pulses of coherent light with a fluency in a range of about 0.1 to 10 J/cm². The pulses of coherent light have a pulse duration in a range of about 100 fs to 5 ps at a pulse repetition frequency in a range of about 1 MHz to 3 GHz. In one embodiment, the pulses of coherent light are delivered in the form of a pulse train in a burst of a micropulse mode lasting microseconds to milliseconds. In another embodiment, the pulses of coherent light are delivered in the form of a pulse train on a continuous basis. Additionally, an infrared laser capable of emitting coherent light of a continuous wave mode can also used to practice the present invention.

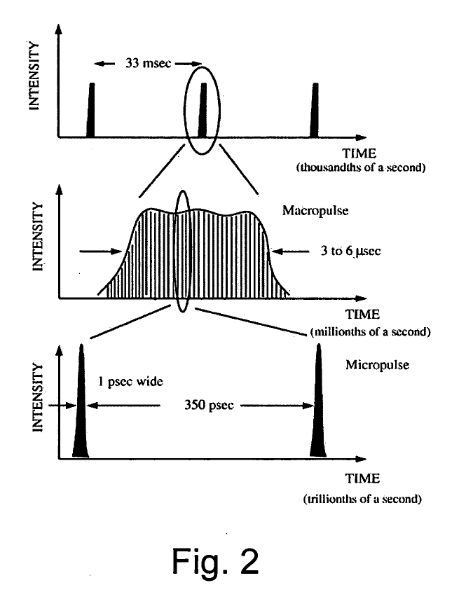

A suitable laser light source for resonant infrared pulsed laser deposition is a FEL that is continuously tunable in the mid-infrared range of 2-10 μm or 5,000-1,000 cm⁻¹. The present data was collected using the FEL at Vanderbilt University in Nashville, Tenn. The Vanderbilt FEL laser produces an approximately 4 μs wide macropulse at a repetition rate of 30 Hz, as shown in FIG. 2. The macropulse is made up of approximately 11,400 1-ps micropulses separated by 350 ps. The energy in each macropulse is on the order of 10 mJ so that the peak unfocused power in each micropulse is very high. The average power of the FEL laser is on the order of 2-3 W. For thin films deposited on a substrate by resonant infrared pulsed laser deposition, as described herein, the fluence is typically between 2 and 3 J/cm² and typical deposition rate is 100 ng/cm²/macropulse although it is in the range of 1 to 300 ng/cm²/pulse.

Other laser sources, for example, CO₂ lasers, OPO lasers, OPA lasers, N₂ lasers, Er:YAG lasers or the like, can also be employed to practice the current invention.

One aspect of the present invention provides a method for transferring a starting material onto a substrate. In one embodiment, the method comprises the steps of vaporizing a starting material, depositing the vaporized material on the substrate, and curing the deposited material on the substrate by cross linking to turn it into a material that is different from the starting material on the substrate.

In one embodiment, the vaporizing steps is performed with coherent light of an infrared wavelength resonant with a vibrational mode of the starting material, wherein the resonant wavelength is determinable from an infrared absorption spectrum of the starting material. The curing step may comprise the step of selectively heating the deposited material at one or more positions of the substrate. In one embodiment, the curing step is performed through a laser light absorption. In another embodiment, the curing step is performed resistively and electrically.

The starting material comprises a precursor solution. In one embodiment, the precursor solution comprises a polyamic acid precursor, and the material comprises polyimide. In another embodiment, the precursor solution comprises a resonant absorbing material characterized in that an ablation process is substantially slow and low-temperature, wherein the resonant absorbing material comprises a solvent N-methyl pyrrolidinone (NMP). Alternatively, the precursor solution comprises a concentration of pyromellitic dianhydride (PMDA) and 4,4′ oxidianiline (ODA) dissolved in N-methyl pyrrolidinone (NMP).

Without intent to limit the scope of the invention, exemplary methods and their related results according to the embodiments of the present invention are given below.

In one of exemplary experiments, a precursor solution from Sigma-Aldrich with an about 15% concentration of PMDA-ODA dissolved in NMP was purchased. A resonant infrared pulsed laser deposition (hereinafter “RIR-PLD”) at a wavelength of 3.45 μm was utilized to deposit the polyamic acid precursor onto a substrate. Fluences required ranged from 0.5 to 3 J/cm². Infrared light appears to transfer the material without causing degradation. This is unique to infrared lasers, since visible and UV lasers cause the polymer to degrade. The successful transfer of the polyamic acid precursor was demonstrated in air as well as under vacuum. Preliminary evaluation of the RIR-PLD transferred polymer indicated that the transferred material was still somewhat soluble in NMP, and the transferred material could easily be removed from the substrate. Thermal curing, e.g., simply heating of the substrate upon which the polyamic acid was deposited, resulted in material that was no longer soluble in NMP and strongly adhered to the substrate. The thermal curing step removes the water and closes the rings in the polyamic acid molecule allowing formation of a rigid 3-D network. The water-removal step requires that the film be thin and uniform to prevent water vapor from becoming trapped. This is qualitative evidence that the transferred material is polyamic acid that has not yet cross-linked to form polyimide.

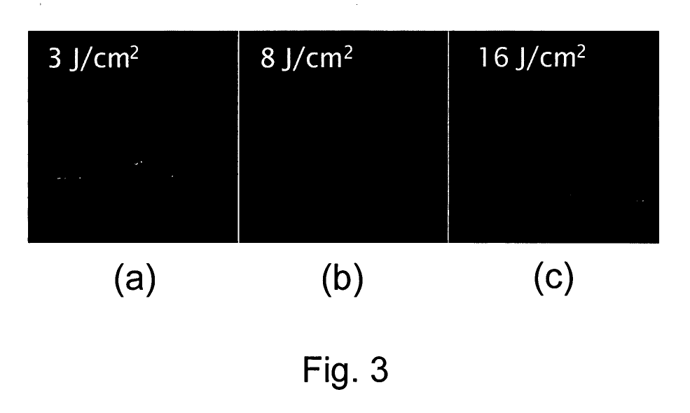

Referring to FIG. 3, images of the plume of a poly(amic)acid (hereinafter “PPA”) solution excited by a N₂ laser were shown according to one embodiment of the present invention. The preliminary PLD experiment was conducted on a precursor solution of 16% PPA in NMP frozen in liquid N₂. A wavelength of 3.45 μm of the N₂ laser, corresponding to a strong vibrational absorbance in the NMP, was employed. The images shown in FIGS. 3a-3c corresponded to the plume excited by the N₂ laser with fluences of 3 J/cm², 8 j/cm² and 16 j/cm², respectively, at a fixed time delay of about 20 μs.

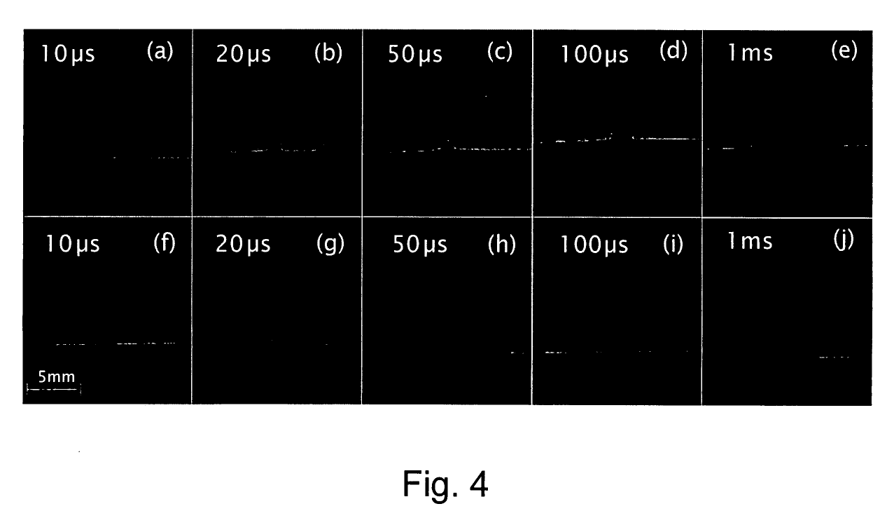

FIG. 4 showed evolution of the plume of a target material excited by a N₂ laser with varied time delays and a fixed fluence. Among them, FIGS. 4a-4e were corresponding to the plume of a neat solvent of NMP excited by the laser with a fixed fluence of 3 J/cm² at time 10 μs, 20 μs, 50 μs, 100 μs, 1 ms, respectively. While FIGS. 4f-4j were corresponding to the plume of PPA solution excited by the laser with a fixed fluence of 3 J/cm² at time 10 μs, 20 μs, 50 μs, 100 μs, 1 ms, respectively. The brightfield plume images of FIG. 4 indicated differences in ablation dynamics between a polymer solution and a neat solvent. The wisps of “smoke” observed in the polymer solution ablation may indicate a possible residual thermal effect when ablation is carried out in air.

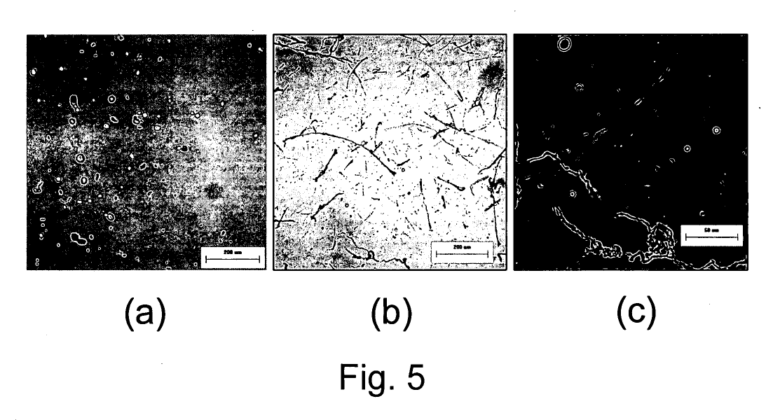

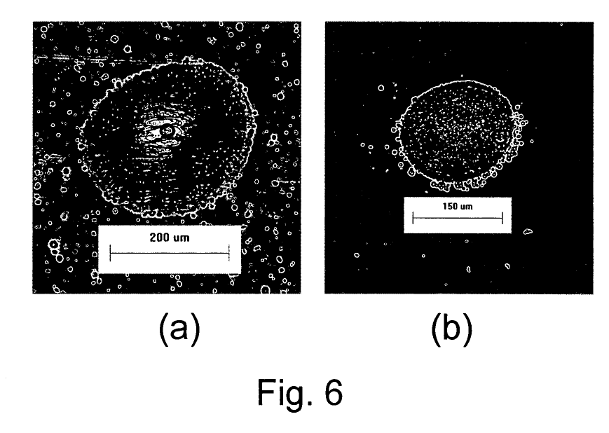

Referring now to FIG. 5, images of the RIR-PLD of polyimide excited by a laser at a wavelength of 3.45 μm were shown according to one embodiment of the present invention. From frozen solutions in vacuum, a mixture of “strings” and droplets were deposited at fluences above 0.5 J/cm², as shown in FIGS. 5b and 5c. Strings and droplets can also be deposited in air from room temperature solutions at fluences between about 0.5 J/cm² and 3 J/cm², as shown in FIG. 5a. At higher fluences, it is possible to suppress “string” formation and transfer primarily large droplets. Polyimide is a thermosetting polymer comprising a rigid 3-D network and being stronger than thermoplastic polymer. Polyimide has a number of desirable properties such as: thermal stability (>500° C.), chemically inert, excellent dielectric properties, and self-extinguishing, which make the polyimide a preferable target material for surface coating in electronics applications. Polyimide films can be deposited by RIR-PLD in air (droplets) and in vacuum (strings), but not from Kapton® film/tape. The ablation of the Kapton® film/tape by the laser of a wavelength of 5.9 μm with fluences above 3 j/cm² was shown in FIG. 6a according to one embodiment of the present invention. While FIG. 6b showed that the ablation of dried PAA film in vacuum had a lower threshold, i.e., visible damage and droplet ejection apparent at 1.5 J/cm². The exemplary studies indicate the RIR-PLD does not appear viable directly from dried PAA films or cured polyimide films such as the Kapton® film/tape because of concomitant thermal damage. However, the PAA precursor and polyimide can be successfully transferred using the RIR-PLD on PAA/NMP solutions, as shown in FIG. 5.

PTFE, due to its dielectric properties, low friction coefficient, chemical inertness, and biocompatibility, is a promising target material for thin film deposition in electronic and medical applications. However, the PTFE is not soluble, thus solution-phase coating is impossible. Other vapor phase techniques cannot produce Teflon® (a brand name of PTFE) or require high temperatures. The RIR-PLD technique disclosed in the present invention has proven to be an effective method for depositing a thin PTFE film onto a substrate [1-3].

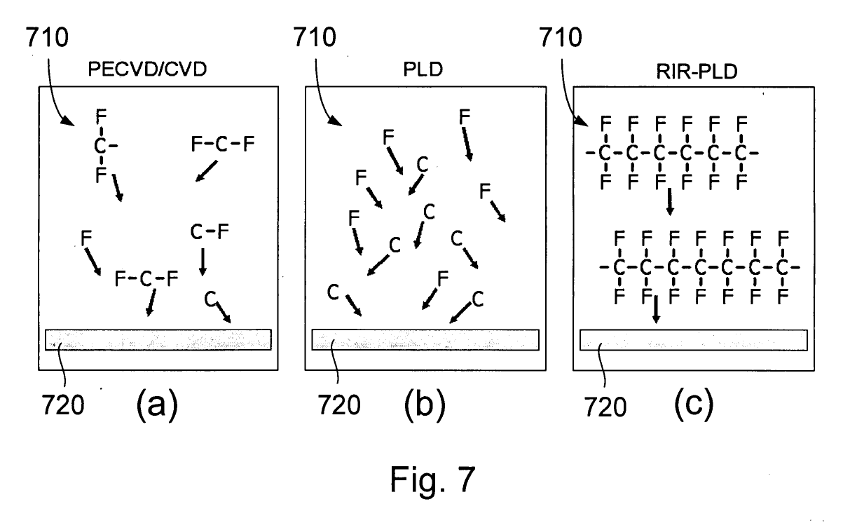

Referring to FIG. 7, mechanisms of transferring PTFE 710 onto a substrate 720 were shown schematically. FIGS. 7a-7c corresponded to a plasma-enhanced chemical vapor deposition (hereinafter “PECVD/CVD”), a conventional PLD and a RIR-PLD of the present invention, respectively.

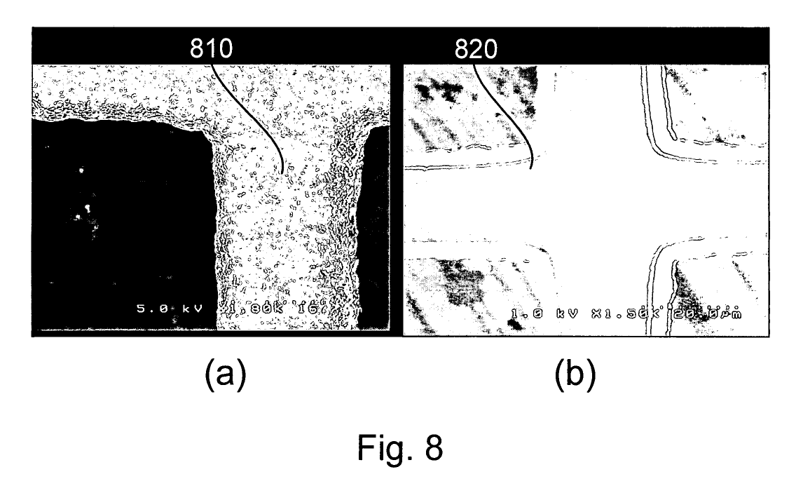

FIG. 8 showed images of (a) a substrate of an uncoated Ni mesh 810 and (b) a coated PTEE film 820 with a thickness of 200 nm onto the substrate 810 according to one embodiment of the present invention. As shown in FIG. 8b, the surface conformability of the coated PTEE film 820 was very good and no corner-rounding is observed, in contrast to wet coating techniques.

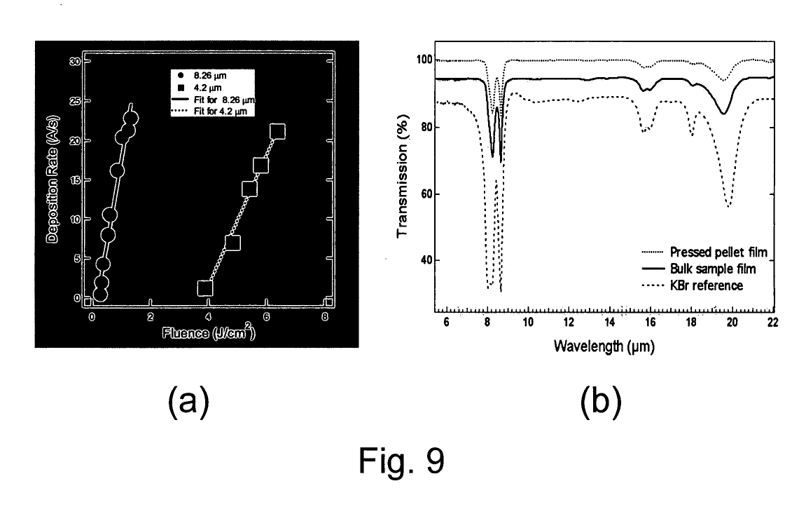

Referring to FIG. 9, graphs of (a) a deposition rate and (b) transmission of a RIR-PLD of PTFE were shown according to one embodiment of the present invention. As shown in FIG. 9a, the deposition rate depended on the resonant wavelength employed. The deposition rate also differed from material to material. Penetration depth was 1.5 μm (30 μm) at the wavelength of 8.26 μm (4.2 μm) implying strong vs weaker local excitation, respectively. Heat-flow calculations show that Tₘₑₗₜ was not reached, but final target temperature higher at the wavelength of 4.2 μm. Low threshold at the wavelength of 8.26 μm gave smoothest films, while at the wavelength of 4.2 μm, ablation dominated by droplet formation.

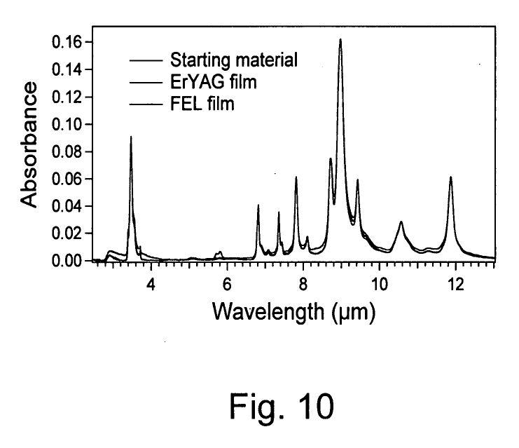

FIG. 10 was thin-film absorption spectra for PEG transferred onto a substrate by means of the RIR-PLD according to one embodiment of the present invention. The absorption spectra of FIG. 10 were respectively corresponding to the absorption spectra of the starting target PEG material, the RIR-PLD PEG film excited by a FEL at a wavelength of about 3.4 μm—a C—H stretch excitation, and the RIR-PLD PEG film excited by a Er:YAG laser at a wavelength of about 2.9 μm—a O—H stretch excitation. The absorption spectra indicated that the PEG has rich vibrational modes. As shown in FIG. 10, all the absorption spectra were almost identical, which indicated that the chemical structure of the RIR-PLD PEG films was substantially same as the structure of the starting PEG polymer.

One aspect of the present invention relates to the use of resonant infrared pulsed laser deposition to transfer a polymer precursor essentially without chemical modification from a frozen target solution containing the precursor to a suitable substrate on which a thin film of the thermoset polymer can be generated by subsequent curing. This opens several important possibilities not available by the conventional methods. A thin precursor film can be selectively irradiated by a laser in such a way that the cured polymer appears only where the laser light causes the precursor to exceed the curing temperature threshold; the substrate can be heated selectively (either resistively or by laser light absorption), leading to topically selected growth of the thermosetting polymer film; if the substrate is such that the polymer cannot wet it, nanoscale grains of the polymer can be generated by heating the entire surface.

The RIR-PLD technique of the present invention can find many applications in a wide spectrum of fields. Among them, some of the applications are given as examples as follows:

Solar Cells (photovoltaic): The cost of organic solar cells can be reduced significantly. The organic solar cells can be used in wireless outdoor lighting, solar-powered cell phones, GPS device for hikers, bikers, campers and construction workers, etc.

Batteries: Polymer batteries have flexible form factors and can be made thinner.

Radio Frequency Identification (RFID): Offering scan-free inventory control and fast checkout at supermarkets, and cost reduction for replacement of barcode labels (<$0.01).

Organic Semiconductors: The main virtue of organic devices is cost, which is the key enabler for some applications. However, manufacturing technology for organic devices is embryonic, needs more attention. The RIR-PLD is a rapid, vacuum-compatible thin-film deposition technique and works well with many different kinds of organic molecules and polymers, which can be used as materials for the next generation “flexible” electronics having advantages, for example, light weight (plastic substrates), low cost (room temperature processing) and wearable and disposable.

Organic/Polymer Light Emitting Diodes (OLED/PLED): The use of the RIR-PLD will significantly simplify processes of manufacturing OLED/PLED and offer control of thin film microstructure to improve mobility and thereby reduce the cost.

Biological Thin Films: Applications for biomaterials in thin film form include, but not limited to, microfluidic biosensors and biochips, advantage drug coatings, “smart” materials such as pH or temperature sensitive polymers, direct drug deposition (proteins, NDA, etc.), and co-deposition of DNA/biopolymers for gene therapy.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

### LIST OF REFERENCES

[1]. D. M. Bubb, M. R. Papantonakis, B. Toftmann, J. S. Horwitz, R. A. McGill, D. B. Chrisey, and R. F. Haglund, Jr., Effect of ablation parameters on infrared pulsed laser deposition of poly(ethylene glycol) films. Journal of Applied Physics, 2002, 91(12): p. 9809-9814.
[2]. D. M. Bubb, M. R. Papantonakis, J. S. Horwitz, R. F. Haglund, Jr., B. Toftmann, R. A. McGill, and D. B. Chrisey, Vapor deposition of polystyrene thin films by intense laser vibrational excitation. Chemical Physics Letters, 2002, 352(3-4): p. 135-139.
[3]. M. R. Papantonakis, M. R. and R. F. Haglund, Jr., Picosecond pulsed laser deposition at high vibrational excitation density: the case of poly(tetrafluoroethylene). Applied Physics A—Materials Science & Processing, 2004, 79(7): p. 1687-1694.

What is claimed is:

1. A method for transferring a material onto a substrate, comprising the steps of:
a. directing a coherent light of a wavelength resonant with a vibrational mode of the material at the material to vaporize the material;
b. depositing the vaporized material on the substrate in a form that is essentially same chemically as the material; and
c. selectively heating the deposited material at one or more positions of the substrate to form a film thereon.

2. The method of claim 1, wherein the material comprises one of organic, inorganic, biological materials and mixtures thereof.

3. The method of claim 2, wherein the material comprises a polymeric material.

4. The method of claim 3, wherein the polymeric material comprises a thermosetting polymer.

5. The method of claim 4, wherein the thermosetting polymer comprises polyimide.

6. The method of claim 3, wherein the polymeric material comprises a thermoplastic polymer.

7. The method of claim 6, wherein the thermoplastic polymer comprises one of polyethylene glycol (PEG), polystyrene, polytetrafluoroethylene (PTFE) and mixtures thereof.

8. The method of claim 3, wherein the polymeric material comprises a polymer precursor solution.

9. The method of claim 8, wherein the polymer precursor solution comprises a concentration of pyromellitic dianhydride (PMDA) and 4,4′ oxidianiline (ODA) dissolved in N-methylpyrrolidinone (NMP).

10. The method of claim 1, wherein the thickness of the film is in a range of a single molecular size to microns, preferably, in a range of about 10 angstroms to 1 μm.

11. The method of claim 1, wherein the vibrational mode of the material is in a range of about 0.1 μm to 10,000 μm.

12. The method of claim 11, wherein the vibrational mode of the material is in the infrared region of about 1 μm to 15 μm, preferably at about 3.45 μm.

13. The method of claim 1, wherein the resonant wavelength of the coherent light is determinable from an absorption spectrum of the material.

14. The method of claim 13, wherein the coherent light comprises pulses of infrared laser with a fluency in a range of about 0.1 to 10 J/cm².

15. The method of claim 14, wherein the pulses of infrared laser have a pulse duration in a range of about 100 fs to 5 ps and a pulse repetition frequency in a range of about 1 MHz to 3 GHz.

16. The method of claim 14, wherein the pulses of infrared laser are delivered in the form of a pulse train in a burst of a micropulse mode lasting microseconds to milliseconds.

17. The method of claim 14, wherein the pulses of infrared laser are delivered in the form of a pulse train on a continuous basis.

18. The method of claim 13, where the coherent light comprises an infrared laser of a continuous wave mode.

19. The method of claim 1, wherein the selectively heating step is performed through a laser light absorption.

20. The method of claim 1, wherein the selectively heating step is performed resistively and electrically.

21. The method of claim 1, wherein the selectively heating step comprises the step of heating the deposited material according to a predetermined pattern.

22. A film made according to the method of claim 1.

23. A method for transferring a material onto a substrate, wherein the substrate is formed such that the material is unable to wet it, comprising the steps of:
a. directing a coherent light of a wavelength resonant with a vibrational mode of the material at the material to vaporize the material;
b. depositing the vaporized material on the substrate in a form that is essentially same chemically as the polymeric material; and
c. heating the deposited material through the substantially entire surface of the substrate in contact with the deposited material to form a plurality of nanoscale grains of the material thereon.

24. The method of claim 23, wherein the material comprises one of organic, inorganic, biological materials and mixtures thereof.

25. A plurality of nanoscale grains of an organic and/or polymeric material made according to the method of claim 23.

26. An apparatus for transferring a material onto a substrate, comprising:
a. a coherent light source of a wavelength resonant with a vibrational mode of the material, wherein the resonant wavelength is determinable from an absorption spectrum of the material;
b. means for directing the coherent light at the polymeric material to vaporize the material;
c. means for depositing the vaporized material on the substrate in a form that is essentially same chemically as the material; and
d. means for selectively heating the deposited material on the substrate.

27. The apparatus of claim 26, wherein the material comprises one of organic, inorganic, biological materials and mixtures thereof.

28. The apparatus of claim 27, wherein the material comprises a polymeric material.

29. The apparatus of claim 26, wherein the vibrational mode of the material is in a range of about 0.1 μm to 10,000 μm.

30. The apparatus of claim 29, wherein the vibrational mode of the material is in the infrared region of about 1 μm to 15 μm, preferably at about 3.45 μm.

31. The apparatus of claim 26, wherein the coherent light source comprises an infrared laser.

32. The apparatus of claim 31, wherein the infrared laser is capable of emitting pulses of coherent light with a fluency in a range of about 0.1 to 10 J/cm².

33. The apparatus of claim 32, wherein the pulses of coherent light have a pulse duration in a range of about 100 fs to 5 ps at a pulse repetition frequency in a range of about 1 MHz to 3 GHz.

34. The apparatus of claim 32, wherein the infrared laser is configured such that the pulses of coherent light are delivered in the form of a pulse train in a burst of a micropulse mode lasting microseconds to milliseconds.

35. The apparatus of claim 32, wherein the infrared laser is configured such that the pulses of coherent light are delivered in the form of a pulse train on a continuous basis.

36. The apparatus of claim 31, where the infrared laser is capable of emitting coherent light of a continuous wave mode.

37. The apparatus of claim 31, where the infrared laser comprises a free electron laser, a CO₂ laser, an OPO laser, a N₂ laser, or an Er:YAG laser.

38. The apparatus of claim 26, wherein the selectively heating means comprises a laser capable of delivering a radiation according to a predetermined pattern.

39. The apparatus of claim 26, wherein the selectively heating means comprises one or more electrical resistors.

40. The apparatus of claim 39, wherein the one or more electrical resistors are adapted for heating the deposited material according to a predetermined pattern.

41. The apparatus of claim 26, wherein the selectively heating means is capable of heating the deposited material at one or more positions of the substrate to form a film thereon.

42. The apparatus of claim 41, wherein the thickness of the film is in a range of a single molecular size to microns, preferably, in a range of about 10 angstroms to 1 μm.

43. The apparatus of claim 26, wherein the substrate is formed such that the material is unable to wet it, and wherein the selectively heating means is capable of heating the deposited material through the substantially entire surface of the substrate in contact with the deposited material to form a plurality of nanoscale grains of the material thereon.

44. The apparatus of claim 26, wherein the selectively heating means is capable of heating the substrate upon which the material is deposited.

45. A method for transferring a starting material onto a substrate, comprising the steps of:
a. vaporizing a starting material;
b. depositing the vaporized material on the substrate; and
c. curing the deposited material on the substrate by cross linking to turn it into a material that is different from the starting material on the substrate.

46. The method of claim 45, wherein the vaporizing steps is performed with coherent light of an infrared wavelength resonant with a vibrational mode of the starting material.

47. The method of claim 46, wherein the resonant wavelength is determinable from an infrared absorption spectrum of the starting material.

48. The method of claim 45, wherein the starting material comprises a precursor solution.

49. The method of claim 48, wherein the precursor solution comprises a polyamic acid precursor.

50. The method of claim 49, wherein the material comprises polyimide.

51. The method of claim 48, wherein the precursor solution comprises a resonant absorbing material characterized in that an ablation process is substantially slow and low-temperature.

52. The method of claim 51, wherein the resonant absorbing material comprises a solvent N-methylpyrrolidinone (NMP).

53. The method of claim 48, wherein the precursor solution comprises a concentration of pyromellitic dianhydride (PMDA) and 4,4′ oxidianiline (ODA) dissolved in N-methylpyrrolidinone (NMP)

54. The method of claim 45, wherein the curing step is performed through a laser light absorption.

55. The method of claim 45, wherein the curing step is performed resistively and electrically.

56. The method of claim 45, wherein the curing step comprises the step of selectively heating the deposited material at one or more positions of the substrate.
